(19) United States
(12) Patent Application Publication
(10) Pub. No.: US 2025/0251653 A1
(43) Pub. Date: Aug. 7, 2025

(54) PROJECTION DISPLAY DEVICE

(71) Applicant: JVCKENWOOD Corporation, Yokohama-shi (JP)

(72) Inventor: Toshiro KONO, Yokohama shi (JP)

(21) Appl. No.: 19/189,447

(22) Filed: Apr. 25, 2025

Related U.S. Application Data
(63) Continuation of application No. PCT/JP2023/037956, filed on Oct. 20, 2023.

(30) Foreign Application Priority Data
Oct. 27, 2022 (JP) 2022-171944

(51) Int. Cl. G03B 21/16; G02F 1/1333; G03B 21/00; G03B 21/20; H05K 7/20

(52) U.S. Cl. CPC G03B 21/16; G02F 1/133385; G03B 21/006; G03B 21/2033; H05K 7/20154; H05K 7/2039; G02F 2203/02

(57) ABSTRACT

A projection display device includes: a reflective liquid crystal display element; a heat sink; a heat source; and a cooling fan. It is assumed that a length of the reflective liquid crystal display element is length L1, a length of the heat source is length L3, and a plate thickness of a base of the heat sink is plate thickness t in at least one direction of a longitudinal direction or a transverse direction of the reflective liquid crystal display element. The reflective liquid crystal display element and the heat source face each other with the base therebetween such that the length L3 of the heat source is located within the length L1 of the reflective liquid crystal display element. The length L3 of the heat source satisfies L3≥L1−2t.

### CROSS-REFERENCE TO RELATED APPLICATIONS

This application is a continuation of PCT Application No. PCT/JP2023/037956, filed on Oct. 20, 2023, and claims the priority of Japanese Patent Application No. 2022-171944 filed on Oct. 27, 2022, the entire contents of both of which are incorporated herein by reference.

### BACKGROUND

The present disclosure relates to a projection display device.

A projection display device has become popular, which uses a reflective liquid crystal display element thereof to modulate illumination light according to an image signal and projects the illumination light onto a screen. It is not preferable to operate the projection display device when the reflective liquid crystal display element has a low temperature, and it is also not preferable if the reflective liquid crystal display element has a high temperature. Therefore, the projection display device includes a configuration for heating the reflective liquid crystal display element or a configuration for cooling the reflective liquid crystal display element (see Japanese Unexamined Patent Application Publication No. 2012-145689 and Japanese Unexamined Patent Application Publication No. 2018-49207).

### SUMMARY

Provision of a projection display device is desired in which a heat source thereof can effectively heat a reflective liquid crystal display element, and the heat source hardly reduces the cooling performance for cooling the reflective liquid crystal display element.

An aspect of one or more embodiments provides a projection display device including: a heat sink configured to include a base with a plate shape; a reflective liquid crystal display element fixed to a first surface of the base; a heat source fixed to a second surface facing the first surface of the base; and a cooling fan configured to apply cooling air to the heat sink, wherein assuming that a length of the reflective liquid crystal display element is length L1, a length of the heat source is length L3, and a plate thickness of the base is plate thickness t in at least one direction of a longitudinal direction or a transverse direction of the reflective liquid crystal display element, the reflective liquid crystal display element and the heat source face each other with the base therebetween such that the length L3 of the heat source is located within the length L1 of the reflective liquid crystal display element, and the length L3 of the heat source satisfies L3≥L1−2t.

### BRIEF DESCRIPTION OF THE DRAWINGS

FIG. 1 is a diagram illustrating a projection display device according to one or more embodiments.

FIG. 2 is a perspective view illustrating a heat sink and a heat source in the projection display device according to one or more embodiments.

FIG. 3 is a cross-sectional view which is taken along line Y1-Y2 in FIG. 2.

FIG. 4 is a characteristic diagram illustrating a relationship between an ambient temperature and an element temperature in the projection display device according to one or more embodiments.

FIG. 5 is a characteristic diagram illustrating a relationship between a value of a light source driving current and an element temperature in the projection display device according to one or more embodiments.

### DETAILED DESCRIPTION

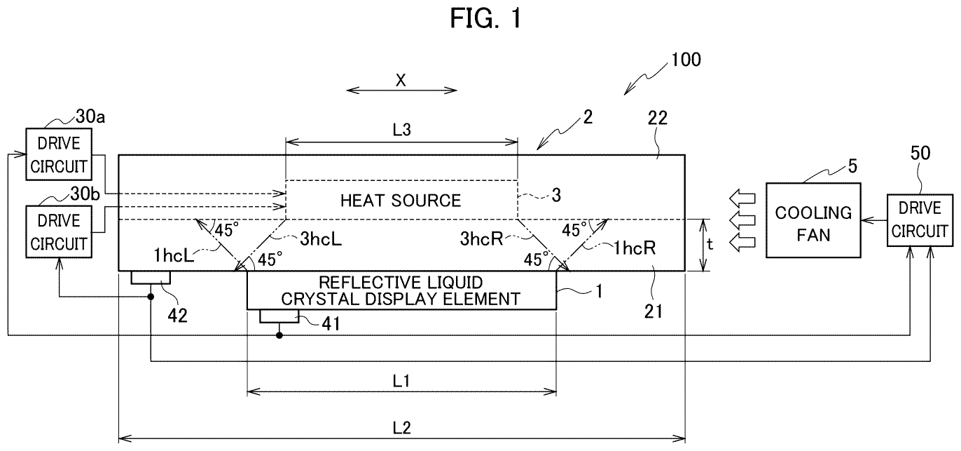

A projection display device according to one or more embodiments will be described below with reference to the accompanying drawings. A projection display device 100 according to one or more embodiments shown in FIG. 1 includes a reflective liquid crystal display element 1, a heat sink 2, a heat source 3, a cooling fan 5, drive circuits 30a and 30b for the heat source 3, temperature sensors 41 and 42, and a drive circuit 50 for the cooling fan 5. The reflective liquid crystal display element 1 is fixed to a first surface of a base 21 of the heat sink 2, and the heat source 3 is fixed to a second surface facing the first surface of the base 21. The cooling fan 5 is disposed behind the heat sink 2.

The projection display device 100 includes three reflective liquid crystal display elements 1 that modulate red light (R light), green light (G light), and blue light (B light). The projection display device 100 is preferably configured as shown in FIG. 1 for the reflective liquid crystal display elements 1 for R light, G light, and B light. The projection display device 100 may be configured as shown in FIG. 1 only for the reflective liquid crystal display element 1 for B light.

An illumination optical system which emits illumination light to the reflective liquid crystal display elements 1 in the projection display device 100, a combining optical system which combines illumination light modulated by the reflective liquid crystal display elements 1 for R light, G light, and B light, and a projection optical system which projects combined light combined by the combining optical system onto a screen have configurations that are not different from conventional configurations, and therefore, FIG. 1 does not show the configurations thereof. The configurations of the illumination optical system, the combining optical system, and the projection optical system may be those disclosed in Patent Literature 2.

However, in the projection display device 100 using a blue laser light source which emits blue laser light as a light source for illumination light, effects by one or more embodiments are particularly exhibited.

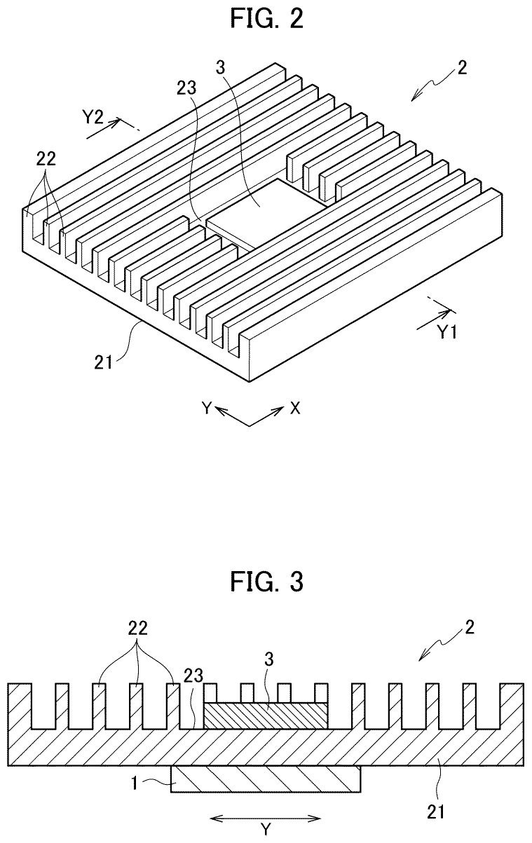

As shown in FIG. 2, the heat sink 2 includes the plate-like base 21 and a plurality of fins 22 which are integrally formed on an upper surface of the base 21. The heat sink 2 is made of aluminum or an aluminum alloy, for example. A central portion of the heat sink 2 has a fin non-forming portion 23 in which the fins 22 are not formed and the upper surface of the base 21 of a predetermined area is exposed. The heat source 3 is fixed on the upper surface of the base 21 of the fin non-forming portion 23.

It is preferable to use a ceramic heater as the heat source 3. Ceramic on a surface of the ceramic heater has a thermal conductivity of about 150 W/m·K, and therefore the thermal conductivity is relatively high. Therefore, when the ceramic heater is used as the heat source 3, the heat generated by the reflective liquid crystal display elements 1 is transmitted to the heat sink 2, and further to the ceramic heater on the fin non-forming portion 23. As a result, the heat can be efficiently radiated into the air. Meanwhile, when a silicon rubber heater is used as the heat source 3, rubber on a surface of the silicon rubber heater has a thermal conductivity of 1.4 to 8 W/m·K, and therefore the thermal conductivity is low. Therefore, although the heat generated by the reflective liquid crystal display elements 1 is transmitted to the heat sink 2, it is difficult for the heat to be transmitted to the silicon rubber heater on the fin non-forming portion 23. As a result, it is not possible to efficiently radiate the heat into the air.

In FIG. 2, an X direction is a longitudinal direction of the reflective liquid crystal display elements 1, and a Y direction is a transverse direction of the reflective liquid crystal display elements 1. FIG. 3 is a cross-sectional view which is taken along line Y1-Y2 in FIG. 2. FIG. 1 shows a state in which the reflective liquid crystal display elements 1 and the heat sink 2 are viewed from side surfaces along the X direction of the heat sink 2.

In FIG. 1, the temperature sensors 41 and 42 are attached to each reflective liquid crystal display element 1 and the heat sink 2, respectively. An output of the temperature sensor 41 is supplied to the drive circuit 30a, and an output of the temperature sensor 42 is supplied to the drive circuit 30b. The drive circuit 30a may be configured using a microprocessor, and the drive circuit 30b may be a simple circuit without using a microprocessor, for example. The temperature sensor 41 may be configured as a circuit in each reflective liquid crystal display element 1. In this case, the temperature sensor 42 may be used, when power is not supplied to each reflective liquid crystal display element 1, and alternatively the temperature sensor 41 may be used, when power is supplied to each reflective liquid crystal display element 1. As the temperature sensor 42 attached to the heat sink 2, a thermistor of which a resistance value changes depending on a temperature can be used.

The drive circuit 30a drives the heat source 3 according to a temperature detected by the temperature sensor 41. The drive circuit 30b drives the heat source 3 according to a temperature detected by the temperature sensor 42.

The drive circuit 30a drives the heat source 3 so that the heat source 3 generates the heat, when a temperature detected by the temperature sensor 41 is a predetermined temperature or lower, while the projection display device 100 operates and each reflective liquid crystal display element 1 is driven. At this time, if the drive circuit 30a is configured using a microprocessor, the drive circuit 30a can control a temperature of each reflective liquid crystal display element 1 with high accuracy.

The drive circuit 30b drives the heat source 3 so that the heat source 3 generates the heat, when a temperature detected by the temperature sensor 42 is the predetermined temperature or lower, while the projection display device 100 does not operate and each reflective liquid crystal display element 1 is not driven. At this time, if a thermistor is used as the temperature sensor 42, a temperature of the heat sink 2 can be detected only by flowing a small current through the temperature sensor 42. Further, if the drive circuit 30b is a simple circuit, a large power is not required to operate the drive circuit 30b, and the heat source 3 can be driven according to a temperature detected by the temperature sensor 42.

In this way, if the projection display device 100 has the temperature sensors 41 and 42 and the drive circuits 30a and 30b, the heat source 3 can be appropriately driven in both a state in which the projection display device 100 does not operate and a state in which the projection display device 100 operates. Even if the projection display device 100 is exposed to a low ambient temperature state for a long time, while the projection display device 100 does not operate, the drive circuit 30b can drive the heat source 3 to keep a temperature of each reflective liquid crystal display element 1 elevated. Therefore, after the projection display device 100 is turned on, and the projection display device 100 starts operating, each reflective liquid crystal display element 1 can be brought to have a desired temperature in a short time. This can shortens the start-up time of the projection display device 100.

When a temperature detected by the temperature sensor 41 or 42 is the predetermined temperature or higher and is high, the drive circuit 50 drives the cooling fan 5 such that the cooling air from the cooling fan 5 is applied to the heat sink 2.

In this way, when the heat source 3 generates heat, the heat is transmitted to each reflective liquid crystal display element 1 through the base 21 of the heat sink 2, and a temperature of each reflective liquid crystal display element 1 rises. When each reflective liquid crystal display element 1 generates heat, while the heat source 3 does not generate heat, the heat is transmitted to the fins 22 through the base 21 of the heat sink 2. Since cooling air from the cooling fan 5 is applied to the heat sink 2, the heat sink 2 radiates heat, and a temperature of each reflective liquid crystal display element 1 decreases.

In the projection display device 100 configured as above, if the area of the heat source 3 in contact with the base 21 of the heat sink 2 is small, it is not possible to effectively heat each reflective liquid crystal display element 1.

Meanwhile, if the area of the heat source 3 in contact with the base 21 of the heat sink 2 is large, the heat radiation performance (cooling performance) of the heat sink 2 may deteriorate.

Therefore, it is necessary that the heat source 3 can effectively heat each reflective liquid crystal display element 1, and that the heat source 3 hardly reduces the cooling performance for cooling each reflective liquid crystal display element 1. That is, it is required to effectively achieve both a heating function of the heat source 3 and a cooling function of the heat sink 2.

As shown in FIG. 1, each reflective liquid crystal display element 1 and the heat source 3 face each other with the base 21 therebetween such that the length L3 of the heat source 3 is located within the length L1 of each reflective liquid crystal display element 1. It is preferable that each reflective liquid crystal display element 1 and the heat source 3 are arranged such that centers thereof in a length direction are aligned.

In FIG. 1, the heat generated by the heat source 3 is efficiently transmitted in a region between two-dot chain line arrows 3hcR and 3hcL in a direction orthogonal to a surface of the base 21, and an angle between the surface and each of the two-dot chain line arrows 3hcR and 3hcL is approximately 45 degrees. Therefore, it is preferable that the length L3 of the heat source 3 satisfies Formula (1) using the length L1 of each reflective liquid crystal display element 1 and the plate thickness t of the base 21. If Formula (1) is satisfied, the heat generated by the heat source 3 can be transmitted to each reflective liquid crystal display element 1 through the heat sink 2 (base 21) without waste.

$$L 3 \geq L 1 - 2 t \qquad ( 1 )$$

When the heat source 3 does not generate heat, the heat generated by each reflective liquid crystal display element 1 is efficiently transmitted in a region between two-dot chain line arrows 1hcR and 1hcL in a direction orthogonal to the surface of the base 21, and an angle between the surface and each of the two-dot chain line arrows 1hcR and 1hcL is approximately 45 degrees. Therefore, in order to enhance the cooling efficiency of the heat sink 2, it is preferable that the length L2 of the heat sink 2 (base 21) satisfies Formula (2) using the length L1 of each reflective liquid crystal display element 1 and the plate thickness t of the base 21.

$$L 2 \geq L 1 + 2 t \qquad ( 2 )$$

The length L1 of each reflective liquid crystal display element 1, the length L2 of the heat sink 2, and the length L3 of the heat source 3, which are shown in FIG. 1 and which are described above, indicate the length in the X direction, which is the longitudinal direction of each reflective liquid crystal display element 1. In the X direction, the projection display device 100 preferably satisfies Formula (1), and more preferably satisfies both Formulas (1) and (2). In the length in the Y direction shown in FIG. 3 also, the projection display device 100 preferably satisfies Formula (1), and more preferably satisfies both Formulas (1) and (2).

The projection display device 100 may satisfy Formula (1) only in at least one direction length of the X direction length and the Y direction length, or may satisfy both Formulas (1) and (2) in at least one direction length. In comparison with a case where the projection display device 100 does not satisfy Formula (1) (or Formulas (1) and (2)) in both the X direction length and the Y direction length, if the projection display device 100 satisfies Formula (1) (or Formulas (1) and (2)) even only in at least one direction length, it is possible to obtain a predetermined effect.

It is preferable that the projection display device 100 satisfies Formula (1) in both the X direction length and the Y direction length. It is more preferable that the projection display device 100 satisfies both Formulas (1) and (2) in both the X direction length and the Y direction length.

In this way, it is sufficient if the projection display device 100 satisfies Formula (1) in at least one direction length of the X direction length and the Y direction length. It is preferable that the projection display device 100 satisfies both Formulas (1) and (2) in at least one direction length of the X direction length and the Y direction length.

When considering the balance between heating by the heat source 3 and cooling by the heat sink 2, Formula (3) provides the best balance. Therefore, it is preferable that the projection display device 100 satisfies Formula (3).

$$L 3 = L 1 - 2 t \qquad ( 3 )$$

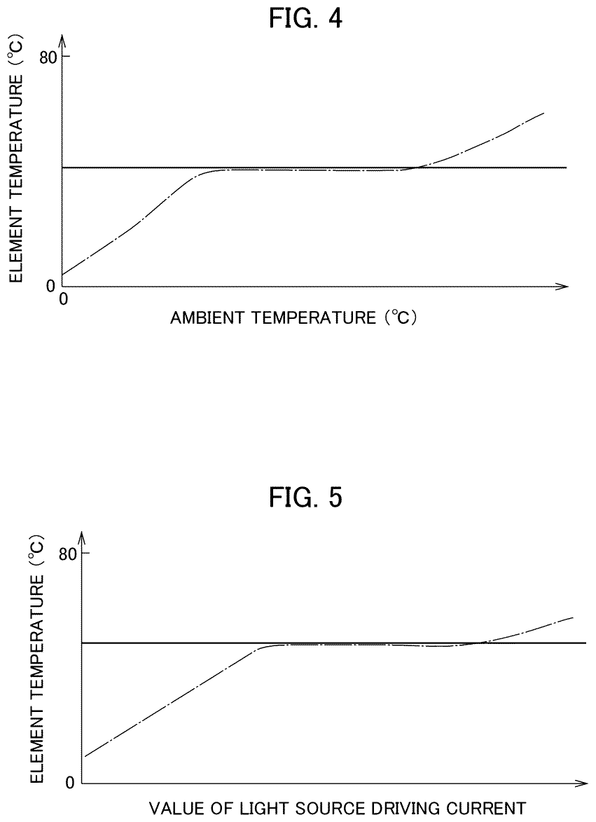

FIG. 4 shows a temperature of each reflective liquid crystal display element 1 (element temperature) when an ambient temperature changes. A one-dot chain line indicates temperature characteristics when the heat source 3 and the cooling fan 5 are not operated, and a solid line indicates temperature characteristics when the heat source 3 and the cooling fan 5 are operated. FIG. 4 shows the temperature characteristics when the projection display device 100 satisfies both Formulas (1) and (2) in both the X direction length and the Y direction length.

When an ambient temperature is low and a temperature of each reflective liquid crystal display element 1 is low, if the heat source 3 is operated, it is possible to operate each reflective liquid crystal display element 1 at an optimum element temperature. When an ambient temperature is high and a temperature of each reflective liquid crystal display element 1 is high, if the cooling fan 5 is operated, it is possible to operate each reflective liquid crystal display element 1 at an optimum element temperature. The projection display device 100 can maintain an element temperature at an optimum element temperature regardless of whether an ambient temperature is high or low.

FIG. 5 shows an element temperature of each reflective liquid crystal display element 1 when a value of a light source driving current changes. A one-dot chain line indicates temperature characteristics when the heat source 3 and the cooling fan 5 are not operated, and a solid line indicates temperature characteristics when the heat source 3 and the cooling fan 5 are operated. FIG. 5 shows the temperature characteristics when the projection display device 100 satisfies both Formulas (1) and (2) in both the X direction length and the Y direction length.

When a value of a light source driving current is small and a temperature of each reflective liquid crystal display element 1 is low, if the heat source 3 is operated, it is possible to operate each reflective liquid crystal display element 1 at an optimum element temperature. When a value of a light source driving current is large and a temperature of each reflective liquid crystal display element 1 is high, if the cooling fan 5 is operated, it is possible to operate each reflective liquid crystal display element 1 at an optimum element temperature. The projection display device 100 can maintain an element temperature at an optimum element temperature regardless of whether a value of a light source driving current is large or small.

When a blue laser light source is used as a light source of illumination light, and an element temperature deviates from an optimum element temperature due to being low or high, interference fringes are likely to occur especially in a B light image. The projection display device 100 of one or more embodiments can reduce interference fringes. It is needless to say that the projection display device 100 of one or more embodiments can display a high quality image, even if the light source of illumination light is a light source other than the blue laser light source.

It is assumed that the three reflective liquid crystal display elements 1 that modulate R light, G light, and B light are first to third reflective liquid crystal display elements, respectively. When a light source of blue light is a blue laser light source, only the third reflective liquid crystal display element of the first to third reflective liquid crystal display elements is used as the reflective liquid crystal display element 1 in FIG. 1. This is sufficient to achieve an effect of reducing interference fringes. It is sufficient if the first and second reflective liquid crystal display elements are fixed to a normal heat sink to which the heat source 3 is not fixed.

As described above, in accordance with the projection display device according to one or more embodiments, the heat source can effectively heat the reflective liquid crystal display elements, and the heat source hardly reduces the cooling performance for cooling the reflective liquid crystal display elements. Therefore, it is possible to operate the reflective liquid crystal display elements at an optimum temperature.

The present invention is not limited to one or more embodiments described above, and various modifications are possible within a scope not departing from a scope of the present invention.

What is claimed is:

1. A projection display device comprising:
a heat sink configured to include a base with a plate shape;
a reflective liquid crystal display element fixed to a first surface of the base;
a heat source fixed to a second surface facing the first surface of the base; and
a cooling fan configured to apply cooling air to the heat sink, wherein
assuming that a length of the reflective liquid crystal display element is length L1, a length of the heat source is length L3, and a plate thickness of the base is plate thickness t in at least one direction of a longitudinal direction or a transverse direction of the reflective liquid crystal display element,
the reflective liquid crystal display element and the heat source face each other with the base therebetween such that the length L3 of the heat source is located within the length L1 of the reflective liquid crystal display element, and
the length L3 of the heat source satisfies L3≥L1−2t.

2. The projection display device according to claim 1, wherein
assuming that a length of the base is length L2 in the at least one direction of a longitudinal direction or a transverse direction of the reflective liquid crystal display element, the length L2 of the base satisfies L2≥L1+2t.

3. The projection display device according to claim 1, wherein the heat sink comprises:
a plurality of fins that are integrally formed on the second surface of the base,
the second surface includes a fin non-forming portion in which the fins are not formed and the second surface is exposed, and
the heat source is fixed to the fin non-forming portion.

4. The projection display device according to claim 1, wherein the heat source is a ceramic heater.

5. The projection display device according to claim 1, wherein
the projection display device comprises: a first reflective liquid crystal display element configured to modulate red light; a second reflective liquid crystal display element configured to modulate green light; and a third reflective liquid crystal display element configured to modulate blue light,
a light source of the blue light is a blue laser light source, and
only the third reflective liquid crystal display element out of the first reflective liquid crystal display element, the second reflective liquid crystal display element, and the third reflective liquid crystal display element is used as the reflective liquid crystal display element.
